(19) United States
(12) Patent Application Publication
(10) Pub. No.: US 2006/0128148 A1
(43) Pub. Date: Jun. 15, 2006

(54) Method of manufacturing semiconductor device

(76) Inventor: Shingo Takahashi, Kanagawa (JP)

Correspondence Address: David R. Metzger;SONNENSCHEIN NATH & ROSENTHAL, Wacker Drive Station, Sears Tower, P.O. Box 061080, Chicago, IL, 60606-1080, US

(21) Appl. No.: 11/287,137

(22) Filed: Nov. 22, 2005

(30) Foreign Application Priority Data
Dec. 9, 2004 (JP) P2004-356633

(51) Int. Cl. H01L 21/44; H01L 21/4763

(52) U.S. Cl. 438/661; 438/652; 438/629; 438/660; 438/650

(57) ABSTRACT

A method of manufacturing a semiconductor device by forming an alloy layer in a connection hole provided in a layer insulation film on a substrate, including a first step of forming a first Cu layer in the state of covering the inside wall of the connection hole, a second step of forming an Ag layer on the first Cu layer, a third step of filling up with a second Cu layer the connection hole provided with the Ag layer, and a fourth step of forming a via composed of a CuAg alloy by diffusion caused by a heat treatment.

### CROSS REFERENCES TO RELATED APPLICATIONS

The present invention contains subject matter related to Japanese Patent Application JP 2004-356633 filed in Japanese Patent Office on Dec. 9, 2004, the entire contents of which being incorporated herein by reference.

### BACKGROUND OF THE INVENTION

The present invention relates to a method of manufacturing a semiconductor device, particularly to a method of manufacturing a semiconductor device which is preferable for forming a multi-layer wiring structure by use of a copper (Cu) alloy wiring.

In recent years, due to the demand for higher degrees of integration of semiconductor devices, Cu has come to be widely used as a material for wirings and plugs. Cu is lower in resistance and higher in electromigration (EM) durability than aluminum (Al), which has been used conventionally.

Attendant on a further progress of miniaturization of the elements, however, generation of EM has come to be a problem even in the wirings made by use of Cu. A Cu film constituting a Cu wiring is usually formed in a wiring trench by sputtering or plating, and, in this case, the Cu film has a form in which a multiplicity of copper particles with a polycrystalline structure are aggregated. When a voltage is supplied on a Cu wiring with such a structure, mass transfer occurs by way of the grain boundaries of the Cu particles, resulting in generation of EM. In a wiring with a small wiring width, the size of the Cu particles is also small, so that the EM problem due to the mass transfer by way of the grain boundaries becomes more conspicuous. Besides, not only the generation of EM but also the generation of stress migration (SM) has also come to be a problem.

In order to solve the EM and SM problems as above, introduction of other metal than Cu, for example silver (Ag), into the Cu wiring has been investigated.

For example, an example has been reported in which silver is introduced into a Cu wiring so as to enhance the recrystallization temperature of the wiring and to reduce the hysteresis width in the temperature-stress curve, thereby enhancing the SM durability of the wiring (see, for example, Japanese Patent Laid-open No. 2004-39916).

In addition, there has also been investigated a method in which a metal other than Cu is diffused into a Cu wiring by a heat treatment so as to form a Cu alloy wiring, thereby enhancing EM durability. As a method of forming such a Cu alloy wiring, an example has been reported in which after the formation of a barrier metal layer at a wiring trench, a seed layer containing in Cu at least one element selected from the group consisting of silver (Ag), arsenic (As), bismuth (Bi), phosphorus (P), antimony (Sb), silicon (Si), and titanium (Ti) is formed, then a Cu layer is formed on the seed layer by plating, and a heat treatment is conducted to thereby form a Cu alloy wiring (see, for example, Japanese Patent Laid-open No. 2000-349085).

Furthermore, an example has been reported in which a recessed portion for wiring is filled up with a first metal film consisting of Cu or containing Cu as a main constituent, thereafter a second metal film containing silver (Ag), niobium (Nb) or aluminum oxide (Al₂O₃) is formed on the first metal film, and a heat treatment is conducted to thereby form a Cu alloy wiring (see, for example, Japanese Patent Laid-open No. Hei 11-204524).

Here, an example of forming a CuAg alloy wiring by, for example, the same method as that described in Japanese Patent Laid-open No. 2000-349085 will be described in detail. As shown in FIG. 6, in a wiring trench 33 provided in a layer insulation film 32 on a substrate 31, a barrier film 34 is formed on the layer insulation film 32 in the state of covering the inside wall of the wiring trench 33. Thereafter, a seed layer 35 of a CuAg alloy is formed on the barrier film 34 by a physical vapor deposition (PVD) process using a Cu alloy containing 1 wt % of Ag as a target.

Next, a Cu layer (not shown) is formed, by an electroplating process, on the seed layer 35 in the state of filling up the wiring trench 33 already provided with the seed layer 35. Subsequently, the Cu layer, the seed layer 35 and the barrier film 34 are removed by a chemical mechanical polishing (CMP) process until the surface of the layer insulation film 32 is exposed, whereby a wiring 36 with a film thickness d inclusive of the seed layer 35 of 200 nm is formed in the wiring trench 33. Thereafter, a heat treatment is conducted at 400° C. for one hour, whereby Ag is diffused from the seed layer 35 composed of the CuAg alloy into the Cu layer, and the wiring 36 composed of a CuAg alloy is formed.

### SUMMARY OF THE INVENTION

However, according to the above-mentioned method of forming a wiring, the distribution of Ag in the wiring 36 composed of a CuAg alloy tends to be uneven. Here, FIG. 7 shows a graph showing the results of measurement of Ag distribution in the wiring 36 by SIMS (Secondary Ion Mass Spectrometry) analysis.

In this graph, the depth from the surface of the wiring is taken on the axis of abscissas, while Ag density and Cu secondary ion intensity are taken on the axis of ordinates. As shown in the graph, it is confirmed that Ag is unevenly distributed heavily in the region where the depth from the surface of the wiring 36 is about 150-200 nm, namely, in the vicinity of the bottom portion where the seed layer 35 is provided, and the Ag density on the bottom portion side is not less than 10²⁰ atoms/cm². On the other hand, the Ag density on the side of the surface of the wiring 36 is 10¹⁹ atoms/cm², namely, lower than that on the bottom portion side by a factor of one order or more.

In addition, as reported in Japanese Patent Laid-open No. Hei 11-204524, even in the case where after the formation of the Cu wiring in the wiring trench, the Ag layer is formed on the Cu wiring and a heat treatment is conducted, it is difficult to evenly distribute Ag in the wiring, like in the above-mentioned manufacturing method.

Accordingly, there is a need for a method of manufacturing a semiconductor device by which Ag can be evenly distributed in a Cu layer.

In order to meet the above-mentioned need, according to an embodiment of the present invention, there is provided a method of manufacturing a semiconductor device by forming an alloy layer in a recessed portion provided in an insulation film on a substrate, wherein the following steps are sequentially carried out. First, in a first step, a first metallic material layer containing a first metallic material is formed in the state of covering the inside wall of the recessed portion. Next, in a second step, a second metallic material layer containing a second metallic material different from the first metallic material is formed on the first metallic material layer. Subsequently, in a third step, the recessed portion provided with the second metallic material layer is filled up with the first metallic material layer. Thereafter, in a fourth step, an alloy layer including the first metallic material and the second metallic material is formed by diffusion caused by a heat treatment.

According to the method of manufacturing a semiconductor device, the heat treatment is conducted in the condition where the second metallic material layer is sandwiched between two first metallic material layers. Therefore, for example, where the first metallic material constituting the first metallic material layer is Cu and the second metallic material constituting the second metallic material layer is Ag, the heat treatment causes diffusion of Ag from the Ag layer into the Cu layer on the lower layer side and into the Cu layer on the upper layer side. This ensures that the Ag diffusion distance necessary for uniform diffusion of Ag into the Cu layers is shorter than that in the case where after the formation of an Ag layer in the state of covering the inside of a recessed portion, the recessed portion provided with the Ag layer is filled up with a Cu layer, or in the case where an Ag layer is formed on a Cu layer provided in a recessed portion. Accordingly, a CuAg alloy layer in the condition where Ag has been more evenly diffused into the recessed portion is formed.

As has been described above, according to the method of manufacturing a semiconductor device of the present invention, a CuAg alloy layer in the condition where Ag has been diffused more evenly can be formed. Therefore, by using this alloy layer as a wiring or a via, Cu migration is restrained, and EM durability and SM durability can be enhanced. Accordingly, a multi-layer wiring structure with a high wiring reliability can be formed.

### BRIEF DESCRIPTION OF THE DRAWINGS

FIGS. 1A to 1B shows manufacturing step sectional diagrams (No. 1) for illustrating a first embodiment of the method of manufacturing a semiconductor device according to the present invention;

FIGS. 1C to 1D shows manufacturing step sectional diagrams (No. 2) for illustrating the first embodiment of the method of manufacturing a semiconductor device according to the present invention;

FIGS. 1E to 1F shows manufacturing step sectional diagrams (No. 3) for illustrating the first embodiment of the method of manufacturing a semiconductor device according to the present invention;

FIG. 2 is a configurational diagram for illustrating a modified example of the first embodiment of the method of manufacturing a semiconductor device according to the present invention;

FIGS. 3A to 3B shows manufacturing step sectional diagrams for illustrating a second embodiment of the method of manufacturing a semiconductor device according to the present invention;

FIG. 4 is a sectional diagram for illustrating a method of manufacturing a semiconductor device according to the related art; and

FIG. 5 is a graph for illustrating the problem in the method of manufacturing a semiconductor device according to the related art.

### DETAILED DESCRIPTION OF THE PREFERRED EMBODIMENTS

### First Embodiment

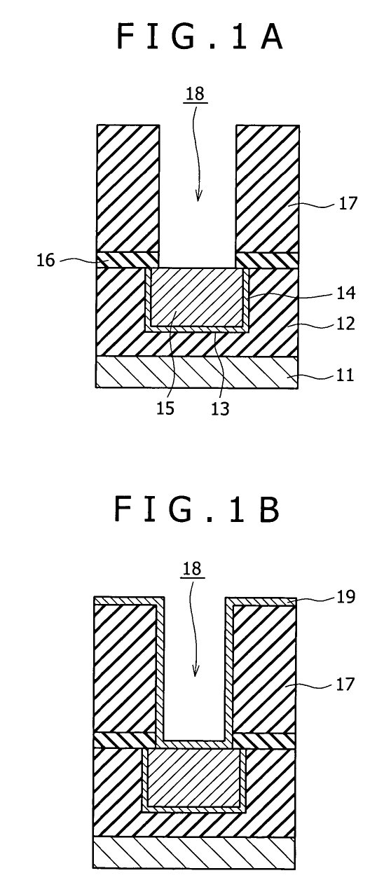

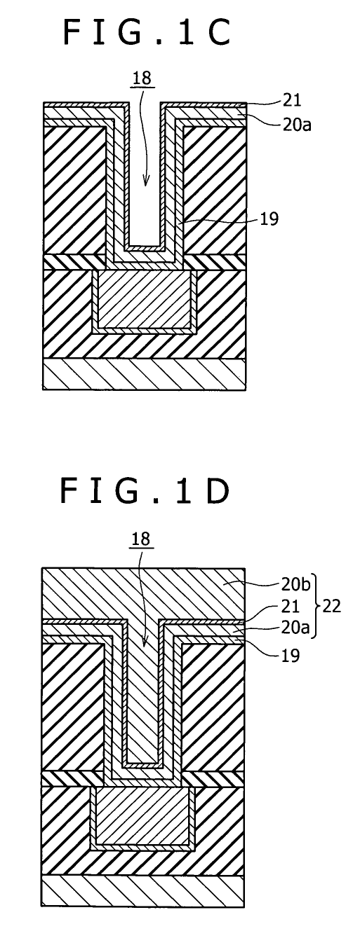

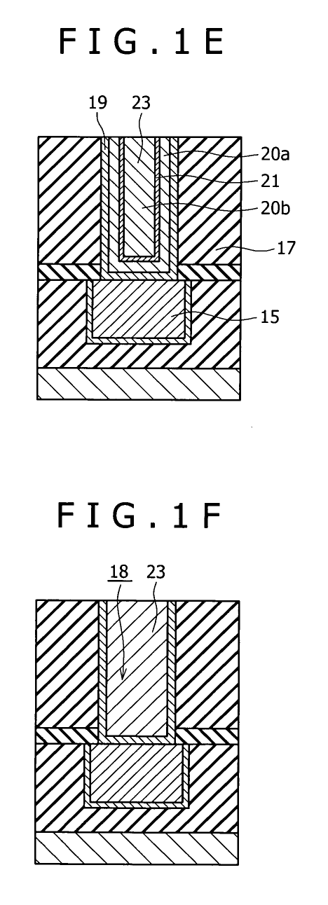

A first embodiment of the method of manufacturing a semiconductor device according to the present invention will be described referring to manufacturing step sectional diagrams shown in FIGS. 1A to 1F. Here, a manufacturing method in which a via composed of a CuAg alloy is formed in a connection hole by a single Damascene process as a trench wiring method will be described.

First, as shown in FIG. 1A, a layer insulation film 12 provided on a substrate 11 composed, for example, of a silicon substrate is already provided with a wiring trench 13, and a lower-layer wiring 15 composed of Cu is already provided in the wiring trench 13, with a barrier film 14 composed, for example, of Ta therebetween. In addition, a protective insulation film 16 composed, for example, of SiN is provided in the condition of covering the upper side of the layer insulation film 12 inclusive of the upper side of the layer-layer wiring 15. The configuration up to this point corresponds to the substrate as set forth in the claims.

Next, a layer insulation film 17 composed, for example, of a silicon oxide (SiO₂) is formed in a thickness of 300 nm on the protective insulation film 16, and then a connection hole 18 reaching the lower-layer wiring 15 is formed in the layer insulation film 17.

Subsequently, as shown in FIG. 1B, a barrier film 19 for preventing diffusion of metal(s) from a via to be formed in the connection hole 18 in a later step into the layer insulation film 17 is formed in a thickness of 5 to 15 nm on the layer insulation film 17 in the state of covering the inside wall of the connection hole 18 by, for example, a PVD process. Here, since the via is formed of a Cu alloy, a material for preventing diffusion of Cu is used for forming the barrier film 19. Examples of such a material include tantalum (Ta), tantalum nitride (TaN), tungsten (W), tungsten nitride (WN), titanium (Ti), titanium nitride (TiN), and titanium nitride silicide (TiSiN). Besides, the barrier film 19 may be a laminate film formed by combining two or more kinds of films of these materials. Incidentally, while the barrier film 19 is formed by the PVD process here, it may be formed by a chemical vapor deposition (PVD) process or an atomic layer deposition (ALD) process.

Next, as shown in FIG. 1C, for example, a first Cu layer 20a (first metallic material layer) composed of Cu as a first metallic material is formed on the barrier film 19, without opening to the atmosphere and in an in-situ mode by, for example, a CVD process. Subsequently, for example, an Ag layer 21 (second metallic material layer) composed of Ag as a second metallic material is formed on the first Cu layer 20a by, for example, a CVD process.

While Ag is used as the second metallic material here, the present invention is not limited to this material selection, inasmuch as the material suppresses or restrains the migration of Cu when added to the Cu layer. Examples of such a material, other than Ag, include As, Bi, P, Sb, Si, Ti, Nb, Al, Mn, Sn, Mg, Au and Al₂O₃, as described in Japanese Patent Laid-open Nos. 2000-349085 and Hei 11-204524 mentioned above in the Background of the Invention. It should be noted here, however, that among these various materials, Ag is preferably used because it can restrain a rise in resistance more assuredly, in the formation of the via composed of an alloy layer by a heat treatment in a later step.

Besides, while a CuAg alloy layer may be formed as the second metallic material layer containing Ag, adoption of the Ag layer is preferred because a high-concentration Ag layer can be formed in a smaller film thickness.

After the Ag layer 21 is formed as has been described above, a second Cu layer 20b (first metallic material layer) composed of Cu, for example, is formed on the Ag layer 21 in the state of filling up the connection hole 18 by, for example, electroplating, as shown in FIG. 1D. In this case, forming the second Cu layer 20b by electroplating is preferable, since the second Cu layer 20b can be thereby formed with favorable filling-up characteristic, as compared with the case of a dry process such as PVD. As a result, a conductive film 22 composed of a sequential lamination of the first Cu layer 20a, the Ag layer 21 and the second Cu layer 20b is provided on the barrier film 19 in the state of filling up the connection hole 18.

Here, by a heat treatment conducted in a later step, Ag is diffused from the Ag layer 21 in the conductive film 22 into the first Cu layer 20a and the second Cu layer 20b, whereby a via composed of a CuAg alloy or alloys is formed in the connection hole 18. As a result, EM durability and SM durability are enhanced, as compared with the case of a Cu layer only, but the resistance of the via is raised. In view of this, the film thickness of the Ag layer 21 is so regulated that the Ag content in the CuAg alloy(s) will be within a range corresponding to an allowable range of the resistance of the via. Specifically, where the Ag content based on the whole body of the conductive film 22 necessary for filling up the connection hole 18 is in the range of 0.1 to 1.5 wt %, the EM durability and SM durability can be enhanced while suppressing the resistance of the via to within the allowable range.

Here, when the Ag content of 0.1 to 1.5 wt % is reduced to the film thickness of the Ag layer 21 under the condition where the thickness of the conductive film 22 is 1000 nm, a film thickness of 0.85 to 12.85 nm is obtained; therefore, the Ag layer 21 is formed to have a film thickness in this range. Here, the first Cu layer 20a is formed in a film thickness of 40 to 100 nm, and the second Cu layer 20b is formed for the filling-up in such a film thickness that the overall thickness of the conductive film 22 will be 1000 nm.

Next, a heat treatment at 200° C. is conducted for growth of crystals of Cu. Thereafter, as shown in FIG. 1E, the conductive film 22 (see FIG. 1D) and the barrier film 19 are removed by, for example, a CMP process until the surface of the layer insulation film 17 is exposed, whereby the via 23 in the state of being in connection with the lower-layer wiring 15 is formed.

The subsequent steps are carried out in the same manner as usual; namely, a protective film is formed on the upper side of the layer insulation film 17 inclusive of the upper side of the via 23, thereafter a layer insulation film is formed on the protective insulation film, a wiring trench in the state of reaching the via is formed in the layer insulation film, and then a wiring is formed in the wiring trench, with a barrier film therebetween, whereby a wiring layer is formed. In this case, heat at about 400° C. is applied during the step of forming the protective insulation film, the step of forming the layer insulation film and the like, and, therefore, the repetition of such a heat treatment step causes Ag to be diffused from the Ag layer 21 into the first Cu layer 20a and the second Cu layer 20B. As a result of the diffusion of Ag, the via 23 is alloyed to be a CuAg alloy, as shown in FIG. 1F.

According to the method of manufacturing a semiconductor device as above, the Ag layer 21 is formed in the state of being sandwiched between the first Cu layer 20a and the second Cu layer 20b, and, by the heat treatment(s) conducted thereafter, Ag is diffused from the Ag layer 21 into the first Cu layer 20a on the lower layer side and the second Cu layer 20b on the upper layer side. This ensures that the diffusion distance for diffusing Ag evenly into the Cu layer(s) by the heat treatment(s) is shortened, as compared with the case where a seed layer composed of a CuAg alloy is formed on a barrier film and then a wiring trench (connection hole) provided with the seed layer is filled up with a Cu layer, or the case where a Cu layer is formed in a wiring trench (connection hole) and then an Ag layer is formed on the Cu layer, as has been described in the Background of the Invention above. Therefore, Ag can be diffused into the via 23 more evenly. Accordingly, Cu migration is restrained, EM durability and SM durability of the via 23 can be enhanced, and, hence, a multi-layer wiring structure with high wiring reliability can be formed.

Incidentally, while an example in which the first Cu layer 20a, the Ag layer 21 and the second Cu layer 20b are sequentially laminated on the barrier film 19 has been described here, a method may be adopted in which an Ag layer, a Cu layer and an Ag layer are sequentially laminated on the barrier film 19. In this case, the Ag layer correspond to the first metal layer in the claims, and the Cu layer corresponds to the second metal layer. In this case, also, the diffusion distance of Ag for diffusing Ag into the Cu layer evenly by heat treatment(s) is shortened, in the same manner as in the manufacturing method according to the first embodiment.

### Modified Example 1

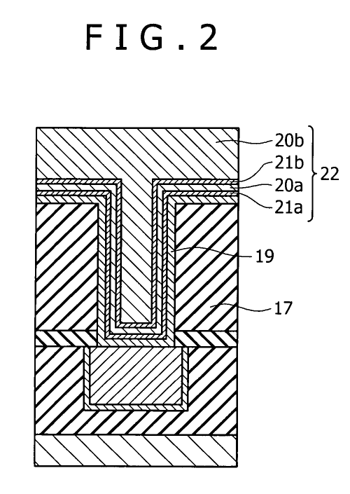

In addition, a method may be adopted in which, as shown in FIG. 2, a first Ag layer 21a is formed on the barrier film 19, then a first Cu layer 20a (first metallic material layer), a second Ag layer 21b (second metallic material layer) and a second Cu layer 20b (first metallic material layer) are sequentially formed on the Ag layer 21a, to form a conductive film 22.

In this case, Ag is to be diffused from the second Ag layer 21b into both the first Cu layer 20a and the second Cu layer 20b, so that the film thickness of the second Ag layer 21b is preferably greater than the film thickness of the first Ag layer 21a. Specifically, the second Ag layer 21b is set to be about two times thicker than the first Ag layer 21a. In this case, also, the Ag content based on the whole body of the conductive film 22 is set in the range of 0.1 to 1.5 wt %, in the same manner as in the first embodiment. Therefore, for the conductive film 22 having a thickness of 1000 nm, the first Ag layer 21a is formed in a film thickness of from 0.28 nm (corresponding to 0.03 wt %) to 4.28 nm (corresponding to 0.5 wt %), and the second Ag layer 21b is formed in a film thickness of from 0.57 nm (corresponding to 0.07 wt %) to 8.56 nm (corresponding to 1.0 wt %). Besides, since Ag is diffused into the first Cu layer 20a from both the first Ag layer 21a and the second Ag layer 21b, the first Cu layer 20a is formed in a larger film thickness than that of the second Cu layer 20b.

The subsequent steps are carried out in the same manner as in the first embodiment, the conductive film 22 and the barrier film 19 are removed until the surface of the layer insulation film 17 is exposed, whereby the via is formed in the connection hole 18, and a heat treatment is conducted, whereby Ag is diffused from the first Ag layer 21a into the first Cu layer 20a, and Ag is diffused from the second Ag layer 21b into the first Cu layer 20a and the second Cu layer 20b.

In the method of manufacturing a semiconductor device as above, also, Ag is diffused from the first Ag layer 21a into the first Cu layer 20a, and Ag is diffused from the second Ag layer 21b into the first Cu layer 20a and the first Cu layer 20b, so that Ag is diffused evenly into the Cu layers, and, therefore, the same effects as in the first embodiment can be displayed.

### Second Embodiment

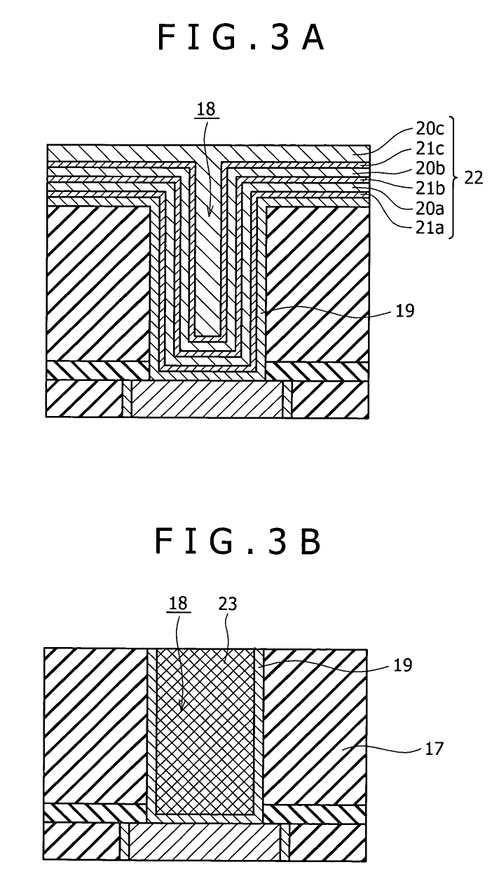

Now, a second embodiment of the method of manufacturing a semiconductor device according to the present invention will be described below referring to manufacturing step sectional diagrams shown in FIG. 3. Incidentally, the same components as in the first embodiment above are denoted by the same reference symbols as used above, and the steps up to the step of forming the barrier film 19 in the state of covering the inside wall of the connection hole 18, as described above referring to FIGS. 1A and 1B, are carried out in the same manner as in the first embodiment.

Next, as shown in FIG. 3A, a first Ag layer 21a is formed on the barrier film 19, and a first Cu layer 20a (first metallic material layer) is formed on the first Ag layer 21a. Thereafter, a second Ag layer 21b (second metallic material layer), a second Cu layer 20b (first metallic material layer) and a third Ag layer 21c (second metallic material layer) are sequentially laminated on the first Cu layer 20a, resulting in the condition where the Ag layers and the Cu layers are alternately laminated. The Ag layers and the Cu layers are formed by PVD, for example; however, CVD and ALD may also be adopted. Thereafter, a third Cu layer 20c (first metallic material layer) is formed on the third Ag layer 21c in the state of filling up the connection hole 18 by, for example, electroplating. This results in the condition where the connection hole 18 is filled up with a conductive film 22 composed of the Ag layers and the Cu layers.

Here, in the same manner as in the first embodiment, the Ag content in the conductive film 22 is in the range of 0.1 to 1.5 wt %. Then, in forming three or more Ag layers in this embodiment, the Ag content in the conductive film 20 is reduced into the film thickness of the Ag layer, and the film thickness is divided by the number of the Ag layers to be formed, whereby the film thickness of each Ag layer is determined. This is preferable in that, by the heat treatment conducted in a later step, Ag can be diffused into the via more evenly. For example, the thickness of the conductive film 20 necessary for filling up the connection hole 18 is 1000 nm, and, when the film thickness of the Ag layers to be formed in the conductive film 20 is reduced from the Ag content in the conductive film 20 which is assumed to be 1.0 wt %, the total thickness of the Ag layers is determined to be 8.56 nm. Here, since the three Ag layers are provided in the conductive film 20, each Ag layer is formed in a film thickness of 2.85 nm.

Incidentally, while three Ag layers are formed in the conductive film 20 here, more than three Ag layers may be formed. In such a case, also, the total thickness of the Ag layers is calculated, and the total thickness is divided by the number of the Ag layers to determine the film thickness of each Ag layer. In addition, while the first Ag layer 21a has been formed on the barrier film 19 here, the first Cu layer 20a may be formed on the barrier film 19 inasmuch as Ag layers and Cu layers are alternately formed. Similarly, while the connection hole 18 has been filled up with the third Cu layer 20c here, the connection hole 18 may be filled up with the third Ag layer 21c inasmuch as Ag layers and Cu layers are alternately formed. Further, while the third Cu layer 20c for the filling-up is formed by electroplating here, the filling-up of the connection hole 18 may be performed by forming the third Cu layer 20c by a dry process such as PVD, CVD, ALD, etc.

The subsequent steps are carried out in the same manner as in the first embodiment. Then, as shown in FIG. 3B, the conductive film 22 (see FIG. 3A) and the barrier film 19 are removed by CMP until the layer insulation film 17 is exposed, whereby the via 23 is formed in the connection hole 18. Next, a protective insulation film is formed on the upper side of the layer insulation film 17 inclusive of the upper side of the via 23, then a layer insulation film is formed on the protective insulation film, a wiring trench reaching the via 23 is formed in the layer insulation film, and thereafter a wiring is formed in the wiring trench, with the barrier film therebetween. In this case, since heat at about 400° C. is applied during the step of forming the protective insulation film, the step of forming the layer insulation film and the like, the repetition of such heat treatment step causes Ag to be diffused from each Ag layer into each Cu layer, whereby the via 23 composed of a CuAg alloy or alloys is formed.

Besides, according to the manufacturing method in this embodiment, since the three Ag layers are formed in the conductive film 22, the Ag layers can be disposed at closer distance to each Cu layer, as compared with the first embodiment. Therefore, the diffusion distance for even diffusion of Ag into the Cu layers is shortened. Accordingly, Ag can be evenly diffused into the Cu layers, even in the case where the heat treatment time in the later steps is short.

Incidentally, while examples in which the via 23 composed of a CuAg alloy layer or layers is formed in the connection hole 18 by the single Damascene process have been described in the first and second embodiments above, the present invention is applicable also to the case where a wiring composed of a CuAg alloy layer or layers is formed in a wiring trench by the single Damascene process. In addition, the present invention is applicable also to the case where a wiring and a via composed of a CuAg alloy layer or layers are formed in a wiring trench and in a connection hole communicated with the wiring trench, which are provided in a layer insulation film, by the dual Damascene process.

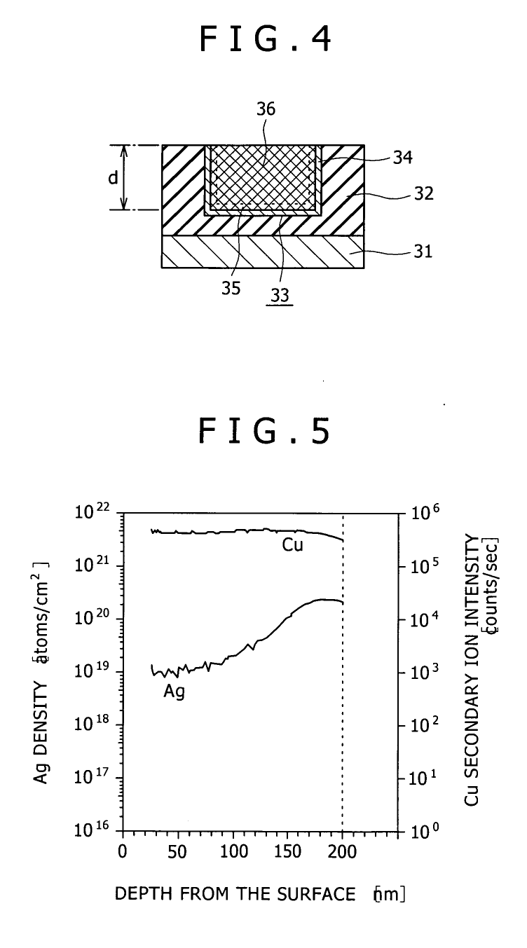

Further, in the case of forming a multi-layer wiring structure, the first embodiment and the second embodiment may be carried out in combination. For example, a via and a wiring provided in a layer insulation film on the lower-layer side in a multi-layer wiring structure are larger in the number of the subsequent film-forming steps and, hence, larger in the number of heating steps to which they will be subjected. In view of this, the lower-layer side is formed in the condition where the Ag layer 21 is sandwiched between the first Cu layer 20a and the second Cu layer 20b, as has been described above using FIG. 3E in the first embodiment. Then, the upper-layer side is formed in the condition where three or more Ag layers are provided in the conductive film 22, so as to dispose the Ag layers at closer distance to each Cu layer, as has been described above using FIG. 5A in the second embodiment. This configuration ensures that the diffusion distance for even diffusion of Ag into the Cu layer(s) is shorter on the upper-layer side than on the lower-layer side, and, hence, a via and a wiring into which Ag has been diffused evenly can be formed, even in the case where the upper layer side is smaller than the lower layer side in the number of heat treatment steps to be applied thereto.

It should be understood by those skilled in the art that various modifications, combinations, sub-combinations and alterations may occur depending on design requirements and other factors insofar as they are within the scope of the appended claims or the equivalents thereof.

What is claimed is:

1. A method of manufacturing a semiconductor device by forming an alloy layer in a recessed portion provided in an insulation film on a substrate, comprising:
a first step of forming a first metallic material layer containing a first metallic material in the state of covering the inside wall of said recessed portion;
a second step of forming a second metallic material layer containing a second metallic material different from said first metallic material, on said first metallic material layer;
a third step of filling up with the first metallic material layer said recessed portion in the state of being provided with said second metallic material layer; and
a fourth step of forming an alloy layer comprised of said first metallic material and said second metallic material through diffusion by a heat treatment.

2. A method of manufacturing a semiconductor device as set forth in claim 1, wherein
said first step and said second step are carried out repeatedly before said third step.

3. A method of manufacturing a semiconductor device as set forth in claim 1, wherein
said third step resides in filling up said recessed portion with said first metallic material layer by a plating process.

4. A method of manufacturing a semiconductor device as set forth in claim 1, wherein
said first metallic material is copper;
a step of forming a barrier film for preventing diffusion of copper from said alloy layer into said insulation film is formed in the state of covering the inside wall of said recessed portion, before said first step; and
said first metallic material layer is formed on said barrier layer in said first step.

5. A method of manufacturing a semiconductor device as set forth in claim 4, wherein
said second metallic material is silver.
